(19) United States
(12) Patent Application Publication
(10) Pub. No.: US 2026/0372171 A1
(43) Pub. Date: Nov. 19, 2026

(54) ELECTRONIC DEVICE, POWER MODULE, AND MANUFACTURING METHOD OF POWER MODULE

(71) Applicant: NIKO SEMICONDUCTOR CO., LTD., NEW TAIPEI CITY (TW)

(72) Inventors: CHUNG-MING LENG, New Taipei City (TW); CHIH-CHENG HSIEH, Taoyuan City (TW); Wei-Lun Wang, NEW TAIPEI CITY (TW)

(21) Appl. No.: 19/433,083

(22) Filed: Dec. 26, 2025

(30) Foreign Application Priority Data
May 15, 2025 (TW) 114118199

(51) Int. Cl. H10W 74/10; H10W 40/47; H10W 74/01

(52) U.S. Cl. CPC H10W 74/114; H10W 40/47; H10W 74/01

(57) ABSTRACT

An electronic device, a power module, and a manufacturing method of a power module. The power module includes a substate, a power chip fixed to an inner metal layer of the substrate, an encapsulant embedding the substrate and the power chip, and a plurality of thermal conduction members fixed to an outer metal layer of the substrate. The outer metal layer is exposed from the encapsulant and is coplanar with an adjacent surface of the encapsulant. Each of the thermal conduction members has a patterning portion and a deformed portion that is connected to the pattering portion. The patterning portions are spaced apart from each other to jointly form a predetermined pattern. Each of the deformed portions is directly connected to the outer metal layer through a bottom part thereof that has a first cross section being greater than a second cross section of the patterning portion.

### CROSS-REFERENCE TO RELATED PATENT APPLICATION

This application claims the benefit of priority to Taiwan Patent Application No. 114118199, filed on May 15, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a power module, and more particularly to an electronic device, a power module, and a manufacturing method of a power module each having a patterned thermal conduction layer.

### BACKGROUND OF THE DISCLOSURE

As heat-dissipation requirements for a conventional power module become higher, the conventional power module is connected to an external heat-dissipation module through a medium (e.g., solder paste or an insulating heat-dissipation paste) for increasing heat-dissipation efficiency. However, the structural design of the conventional power module itself has not improved for increasing heat-dissipation efficiency.

### SUMMARY OF THE DISCLOSURE

In response to the above-referenced technical inadequacies, the present disclosure provides an electronic device, a power module, and a manufacturing method of a power module for effectively improving on the issues associated with conventional power modules.

In order to solve the above-mentioned problems, one of the technical aspects adopted by the present disclosure is to provide a manufacturing method of a power module, which includes a chip-bonding step, a packaging step, and a patterning step. The chip-bonding step is implemented by fixing a power chip onto an inner metal layer of a substrate. The substrate includes an outer metal layer that is opposite to the inner metal layer and that is not electrically coupled to the power chip. The packaging step is implemented by encapsulating the substrate and the power chip in an encapsulant and exposing a flat layout surface of the outer metal layer of the substrate from the encapsulant. The flat layout surface is coplanar with a surface of the encapsulant adjacent thereto. The patterning step is implemented by directly fixing deformed portions of a plurality of thermal conduction members onto the flat layout surface. Each of the thermal conduction members has a patterning portion that is connected to an upper side of the deformed portion thereof. In each of the thermal conduction members, an area of a first cross section of a bottom part of the deformed portion is greater than an area of a second cross section of the patterning portion. After the pattering step is implemented, the patterning portions of the thermal conduction members are spaced apart from each other and are arranged adjacent to each other so as to jointly define a predetermined pattern.

In order to solve the above-mentioned problems, another one of the technical aspects adopted by the present disclosure is to provide a power module, which includes a substrate, a power chip, an encapsulant, and a patterned thermal conduction layer. The substrate includes a board, an inner metal layer formed on one side of the board, and an outer metal layer that is formed on another side of the board. The power chip is fixed onto the inner metal layer of the substrate and is not electrically coupled to the outer metal layer. The outer metal layer has a flat layout surface arranged away from the power chip. The substrate and the power chip are embedded in the encapsulant, and the flat layout surface of the outer metal layer is exposed from the encapsulant and is coplanar with a surface of the encapsulant adjacent thereto. The patterned thermal conduction layer includes a plurality of thermal conduction members directly fixed onto the flat layout surface. Each of the thermal conduction members has a patterning portion and a deformed portion. The patterning portions of the thermal conduction members are spaced apart from each other and are arranged adjacent to each other, and jointly define a predetermined pattern. The deformed portion is connected to the patterning portion through an upper side thereof and is directly connected to the flat layout surface through a bottom part thereof. An area of a first cross section of the bottom part of the deformed portion is greater than an area of a second cross section of the patterning portion.

In order to solve the above-mentioned problems, yet another one of the technical aspects adopted by the present disclosure is to provide an electronic device, which includes a power module and a liquid cooling module assembled to the power module.

The power module includes a substrate, a power chip, an encapsulant, and a patterned thermal conduction layer. The substrate includes a board, an inner metal layer formed on one side of the board, and an outer metal layer that is formed on another side of the board. The power chip is fixed onto the inner metal layer of the substrate and is not electrically coupled to the outer metal layer. The outer metal layer has a flat layout surface arranged away from the power chip. The substrate and the power chip are embedded in the encapsulant, and the flat layout surface of the outer metal layer is exposed from the encapsulant and is coplanar with a surface of the encapsulant adjacent thereto. The patterned thermal conduction layer includes a plurality of thermal conduction members directly fixed onto the flat layout surface. Each of the thermal conduction members has a patterning portion and a deformed portion. The patterning portions of the thermal conduction members are spaced apart from each other and are arranged adjacent to each other, and jointly define a predetermined pattern. The deformed portion is connected to the patterning portion through an upper side thereof and is directly connected to the flat layout surface through a bottom part thereof. An area of a first cross section of the bottom part of the deformed portion is greater than an area of a second cross section of the patterning portion. The liquid cooling module has a coolant channel, and the patterned thermal conduction layer of the power module is arranged in the coolant channel.

Therefore, in any one of the electronic device, the power module, and the manufacturing method provided by the present disclosure, through the structural difference between the patterning portion and the deformed portion of each of the thermal conduction members, when the predetermined pattern is formed by the patterning portions, the connection area of the patterning thermal conduction layer and the flat layout surface can be increased for effectively increasing thermal conduction efficiency from the outer metal layer to each of the thermal conduction members.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a manufacturing method of a power module according to a first embodiment of the present disclosure;

FIG. 2 is a schematic cross-section view showing a chip-bonding step of FIG. 1;

FIG. 3 is a schematic cross-section view showing a packaging step of FIG. 1;

FIG. 4 is a schematic cross-section view showing a patterning step of FIG. 1;

FIG. 5 is a schematic perspective view showing the power module of FIG. 4;

FIG. 6 is a schematic cross-section view showing the power module of FIG. 4 in another configuration;

FIG. 7 is a schematic perspective view showing the power module in another configuration according to the first embodiment of the present disclosure;

FIG. 8 is a schematic perspective view showing the power module in yet another configuration according to the first embodiment of the present disclosure;

FIG. 9 is a schematic cross-section view showing a strengthening step of the manufacturing method according to a second embodiment of the present disclosure;

FIG. 10 is a schematic cross-section view of the power module according to the second embodiment of the present disclosure; and

FIG. 11 is a schematic cross-section view of an electronic device according to a third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

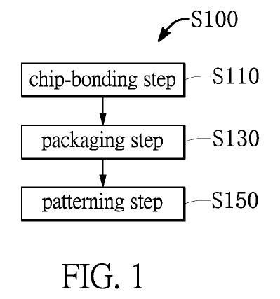

Referring to FIGS. 1 -8, a first embodiment of the present disclosure is provided. As shown in FIGS. 1-5 the present embodiment provides a power module 100 and a manufacturing method S100 thereof. In order to clearly describe the present embodiment, the following description describes the manufacturing method S100 and then describes a structure of the power module 100. The manufacturing method S100 includes a chip-bonding step S110, a packaging step S130, and a patterning step S150, and the following description approximately describes an implementation of each of the above steps, but the present disclosure is not limited thereto.

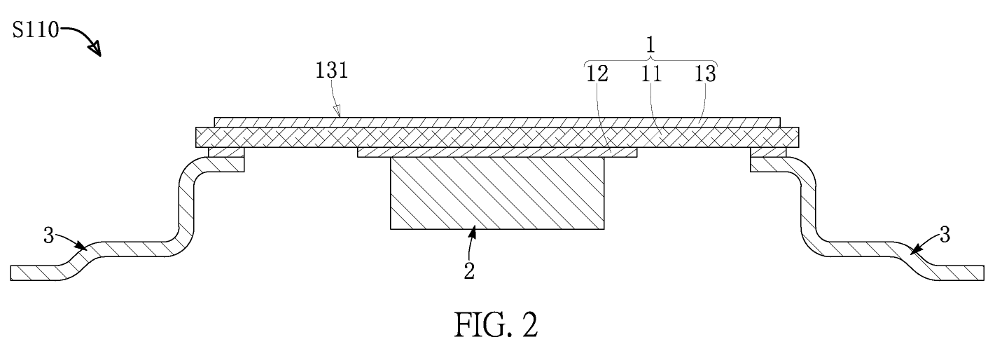

As shown in FIGS. 1 and 2, the chip-bonding step S110 is implemented by fixing a power chip 2 onto an inner metal layer 12 of a substrate 1. The substrate 1 includes an outer metal layer 13 that is opposite to the inner metal layer 12 and that is not electrically coupled to the power chip 2. In other words, a step or a structure provided for electrically coupling an outer metal layer and a power chip is not the chip-bonding step S110 of the present embodiment.

In the present embodiment, the inner metal layer 12 and the outer metal layer 13 are respectively arranged on two opposite sides of the substrate 1 and are not electrically coupled to each other, the inner metal layer 12 and the outer metal layer 13 are made of a high thermal conductivity material (e.g., a copper alloy) that has a thermal conductivity being greater than 40 W/m•k, and the substrate 1 can be a direct bonded copper (DBC) substrate, a direct plated copper (DPC) substrate, an active metal brazing (AMB) substrate, or a printed circuit board (PCB) according to practical requirements, but the present disclosure is not limited thereto.

Specifically, the outer metal layer 13 in the present embodiment has a flat layout surface 131 arranged away from the power chip 2 for implementation of the following steps. Moreover, a specific structure or a quantity of any one of the inner metal layer 12, the outer metal layer 13, and the power chip 2 can be adjusted or changed according to practical requirements. For example, in other embodiments of the present disclosure not shown in the drawings, each of the inner metal layer 12, the outer metal layer 13 can include a plurality of regions separate from each other, a quantity of the power chip 2 are more than one, and the power chips 2 are respectively mounted onto the regions of the inner metal layer 12.

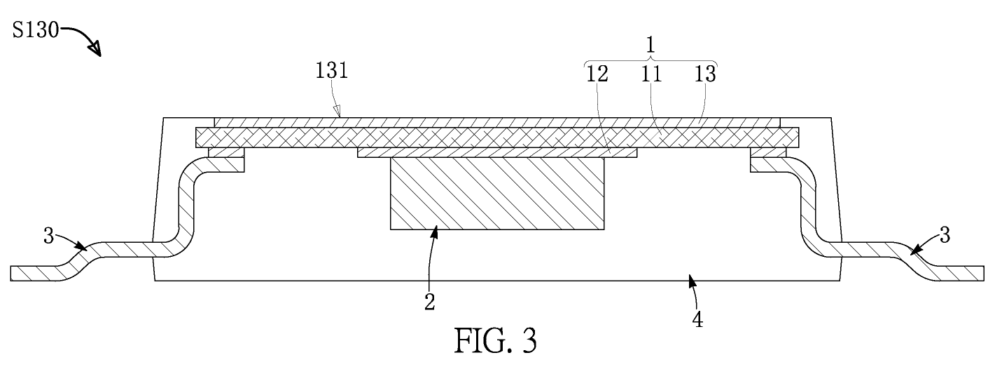

As shown in FIGS. 1 and 3, the packaging step S130 is implemented by encapsulating the substrate 1 and the power chip 2 in an encapsulant 4 and exposing the flat layout surface 131 of the outer metal layer 13 from the encapsulant 4. The flat layout surface 131 is coplanar with a surface of the encapsulant 4 (e.g., a top surface of the encapsulant 4 shown in FIG. 3) adjacent thereto. In other words, a part of the substrate 1 and the power chip 2 exposed from the encapsulant 4 is only the flat layout surface 131. Moreover, the encapsulant 4 in the present embodiment is a molding compound, but the present disclosure is not limited thereto.

It should be noted that the chip-bonding step S110 of the present embodiment can be implemented by further fixing a plurality of pins 3 onto the inner metal layer 12 so as to enable the pins 4 to be electrically coupled to the power chip 2. Moreover, in the packaging step S130, a part of each of the pins 3 is embedded in the encapsulant 4, and another part of each of the pins 3 is exposed (or protrudes) from the encapsulant 4.

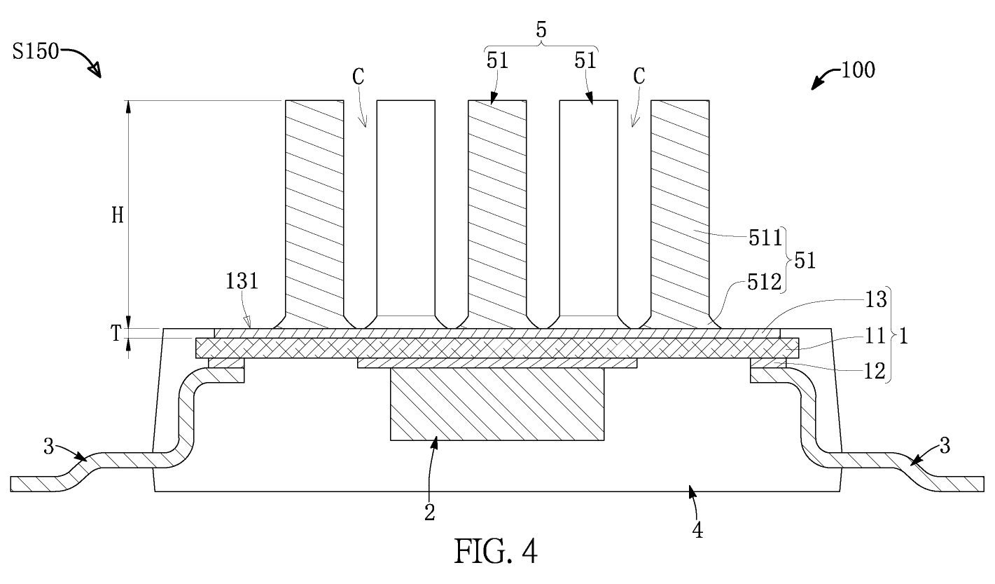

As shown in FIGS. 1 and 4, the patterning step S150 is implemented by directly fixing deformed portions 512 of a plurality of thermal conduction members 51 onto the flat layout surface 131. Each of the thermal conduction members 51 has a patterning portion 511 that is connected to an upper side of the deformed portion 512 thereof. In each of the thermal conduction members 51, an area of a first cross section of a bottom part of the deformed portion 512 is greater than an area of a second cross section of the patterning portion 511.

As the thermal conduction members 51 in the present embodiment are of substantially the same structure, the following description discloses the structure of just one of the thermal conduction members 51 for the sake of brevity, but the present disclosure is not limited thereto. For example, in other embodiments of the present disclosure not shown in the drawings, the thermal conduction members 51 can be of different structures.

In the patterning step S150 provided by the present embodiment, the area of the first cross section of the bottom part of the deformed portion 512 is within a range from 110% to 150% of the area of the second cross section of the patterning portion 511, the area of the first cross section of the bottom part of the deformed portion 512 is at least 50% of an area of the flat layout surface 131, and a height H of each of the thermal conduction members 51 relative to the flat layout surface 131 is greater than at least three times of a thickness T of the outer metal layer 13, but the present disclosure is not limited thereto.

Specifically, each of the thermal conduction members 51 can be made of a high thermal conductivity material that has a thermal conductivity being greater than 40 W/m•k. For example, each of the thermal conduction members 51 can be made of a copper alloy, and the bottom part of the deformed portion 512 of each of the thermal conduction members 51 is welded onto the flat layout surface 131; or, each of the thermal conduction members 51 can be made of an aluminum alloy, and the bottom part of the deformed portion 512 of each of the thermal conduction members 51 is eutectic bonded onto the flat layout surface 131. In addition, each of the thermal conduction members 51 and the outer metal layer 13 can be connected to each other in a laser welding manner or an ultrasonic welding manner, and each of the thermal conduction members 51 and the flat layout surface 131 preferably have no medium (e.g., solder or conductive paste) arranged therebetween, but the present disclosure is not limited thereto.

Moreover, after the patterning step S150 is implemented, the patterning portions 511 of the thermal conduction members 51 are spaced apart from each other and are arranged adjacent to each other so as to jointly define a predetermined pattern. In the present embodiment, thermal conduction members 51 can be selected in quantity, arrangement, and/or structure according to practical requirements to form different kinds of the predetermined pattern. In other words, each of the thermal conduction members 51 is a unit region of the predetermined pattern, and cannot independently form one kind of pattern.

The above description describes the manufacturing method S100, and the power module 100 can be manufactured by implementing the manufacturing method S100, such that structural features of the power module 100 can be referred to the above description of the manufacturing method S100, but the present disclosure is not limited thereto. For example, in other embodiments of the present disclosure not shown in the drawings, the power module 100 can be manufactured by implementing a method other than the manufacturing method S100. The following description describes the structural features of the power module 100 provided by the present embodiment.

As shown in FIGS. 4-8, the power module 100 in the present embodiment includes a substrate 1, a power chip 2 fixed to the substrate 1, a plurality of pins 3 fixed to the substrate 1, an encapsulant 4, and a patterned thermal conduction layer 5 that is directly fixed to the substrate 1. The substrate 1 includes a board 11, an inner metal layer 12 formed on one side of the board 11, and an outer metal layer 13 that is formed on another side of the board 11.

Specifically, the board 11 is a flat and insulative board (e.g., a ceramic board or a plastic board), the inner metal layer 12 and the outer metal layer 13 are respectively formed on two opposite surfaces of the board 11, and the outer metal layer 13 has a flat layout surface 131 arranged away from the inner metal layer 12 (or the power chip 2). In other words, the flat layout surface 131 in the present embodiment does not have any undulating structure.

The power chip 2 is fixed to the inner metal layer 12 of the substrate 1 and is not electrically coupled to the outer metal layer 13, and the pins 3 are fixed to the inner metal layer 12 and are electrically coupled to the power chip 2, but the present disclosure is not limited thereto. For example, in other embodiments of the present disclosure not shown in the drawings, any one of the pins 3 can be fixed to the substrate 1 in other manners (e.g., an insertion manner).

In addition, an electrical connection of the power chip 2 and the inner metal layer 12 can be established in a flip-chip manner or a wire-bonding manner according to practical requirements. Moreover, the inner metal layer 12 can include a plurality of regions provided for fixing the power chip 2 and the pins 3, but the present disclosure is not limited thereto.

The substrate 1 and the power chip 2 are embedded in the encapsulant 4, and the flat layout surface 131 of the outer metal layer 13 is exposed from the encapsulant 4 and is coplanar with a surface of the encapsulant 4 adjacent thereto. In other words, a part of the substrate 1 and the power chip 2 exposed from the encapsulant 4 is only the flat layout surface 131. Moreover, a part of each of the pins 3 is embedded in the encapsulant 4, and another part of each of the pins 3 is exposed (or protrudes) from the encapsulant 4.

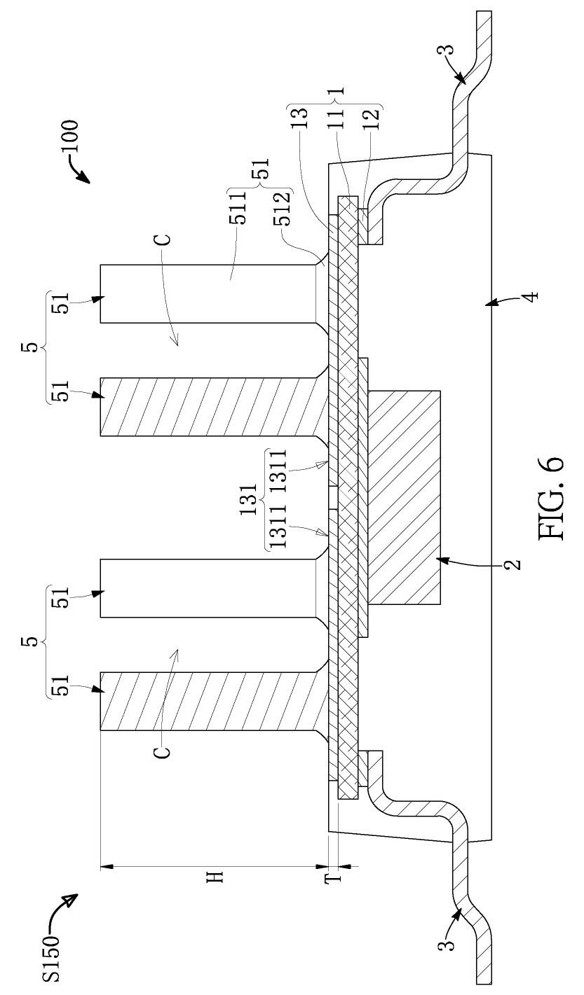

The patterned thermal conduction layer 5 includes a plurality of thermal conduction members 51. The flat layout surface 131 can be a single flat surface as shown in FIG. 4, and the thermal conduction members 51 are directly fixed onto the flat layout surface 131. Or, the flat layout surface 131 can include a plurality of sub-surfaces 1311 spaced apart from each other as shown in FIG. 6, and the thermal conduction members 51 are directly fixed onto the sub-surfaces 1311 of the flat layout surface 131, respectively. It should be noted that a height H of each of the thermal conduction members 51 relative to the flat layout surface 131 in the present embodiment is greater than at least three times of a thickness T of the outer metal layer 13. In other words, a multi-layer conductive structure stacked on any board is different from the thermal conduction member 51 provided by the present embodiment.

Specifically, the thermal conduction members 51 and the flat layout surface 131 jointly define a thermal conduction channel C that is configured to allow a thermal conduction medium (e.g., a coolant) to flow therethrough. Each of the thermal conduction members 51 has a patterning portion 511 and a deformed portion 512 that is connected to the patterning portion 511 through an upper side thereof. The patterning portions 511 of the thermal conduction members 51 are spaced apart from each other and are arranged adjacent to each other, and jointly define a predetermined pattern.

Moreover, the deformed portion 512 of each of the thermal conduction members 51 is directly connected to the flat layout surface 131 through a bottom part thereof, and the deformed portions 512 of the thermal conduction members 51 can be connected to each other or can be spaced apart from each other, but the present disclosure is not limited thereto. In the present embodiment, an area of a first cross section of the bottom part of the deformed portion 512 is greater than an area of a second cross section of the patterning portion 511. For example, the area of the first cross section of the bottom part of the deformed portion 512 is within a range from 110% to 150% of the area of the second cross section of the patterning portion 511, and the area of the first cross section of the bottom part of the deformed portion 512 is at least 50% of an area of the flat layout surface 131. In other words, the bottom part of the deformed portion 512 is connected to at least 50% of the area of the flat layout surface 131.

Accordingly, through the structural difference between the patterning portion 511 and the deformed portion 512 of each of the thermal conduction members 51, when the predetermined pattern is formed by the patterning portions 511, the connection area of the patterning thermal conduction layer 5 and the flat layout surface 131 can be increased for effectively increasing thermal conduction efficiency from the outer metal layer 13 to each of the thermal conduction members 51.

Specifically, the outer metal layer 13 and each of the thermal conduction members 51 are made of a high thermal conductivity material that has a thermal conductivity being greater than 40 W/m•k, and the bottom part of the deformed portion 512 of each of the thermal conduction members 51 is welded onto the flat layout surface 131. Or, the outer metal layer 13 and each of the thermal conduction members 51 are made of a copper alloy or an aluminum alloy, and the bottom part of the deformed portion 512 of each of the thermal conduction members 51 is eutectic bonded onto the flat layout surface 131.

In addition, thermal conduction members 51 provided by the present embodiment can be selected in quantity, arrangement, and/or structure according to practical requirements to form different kinds of the predetermined pattern, and the following description describes a suitable structure of the thermal conduction member 51 for some of the kinds, but the present disclosure is not limited thereto.

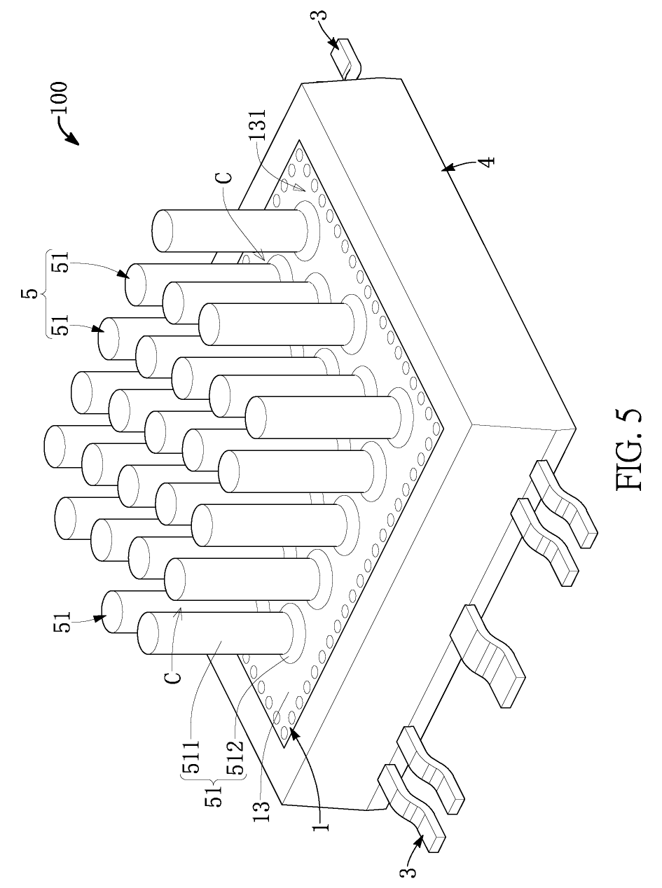

As shown in FIGS. 4 and 5 , each of the thermal conduction members 51 is an elongated column (e.g., a circular column), and the thermal conduction members 51 are parallel to each other. The thermal conduction members 51 shown in the drawings are of substantially the same structure, but in other embodiments of the present disclosure not shown in the drawings, the thermal conduction members 51 can be of different structures (e.g., the thermal conduction members 51 having different heights, different diameters, and/or different shapes).

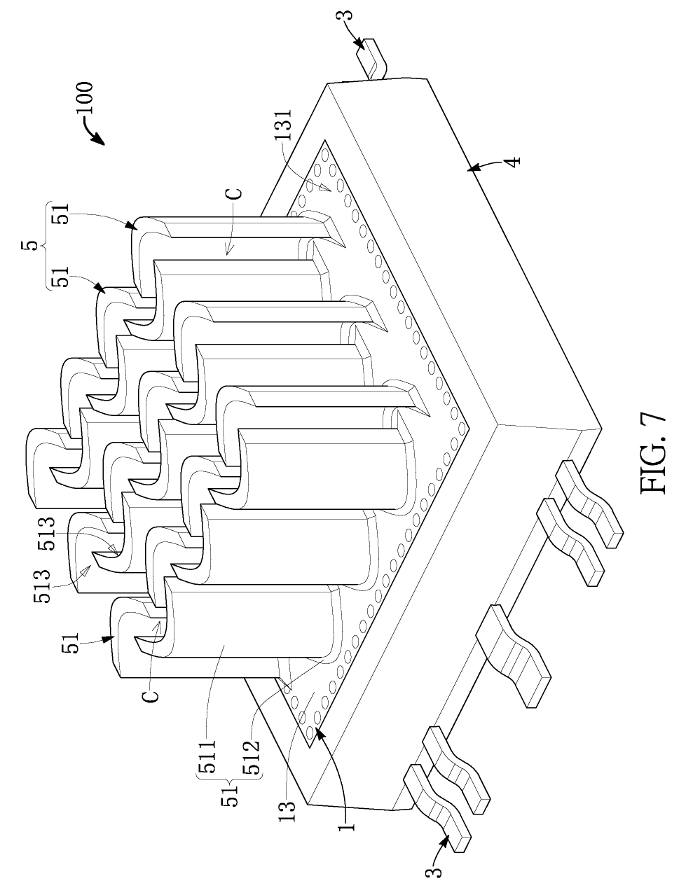

As shown in FIG. 7, each of the thermal conduction members 51 can substantially be a C-shaped column and has a C-shaped side surface 513. In at least two of the thermal conduction members 51 adjacent to each other, the C-shaped side surfaces 513 of the patterning portions 511 are staggered with each other, and a part of one of the C-shaped side surfaces 513 is arranged in a space surrounded by another one of the C-shaped side surfaces 513 for jointly defining an S-shaped space.

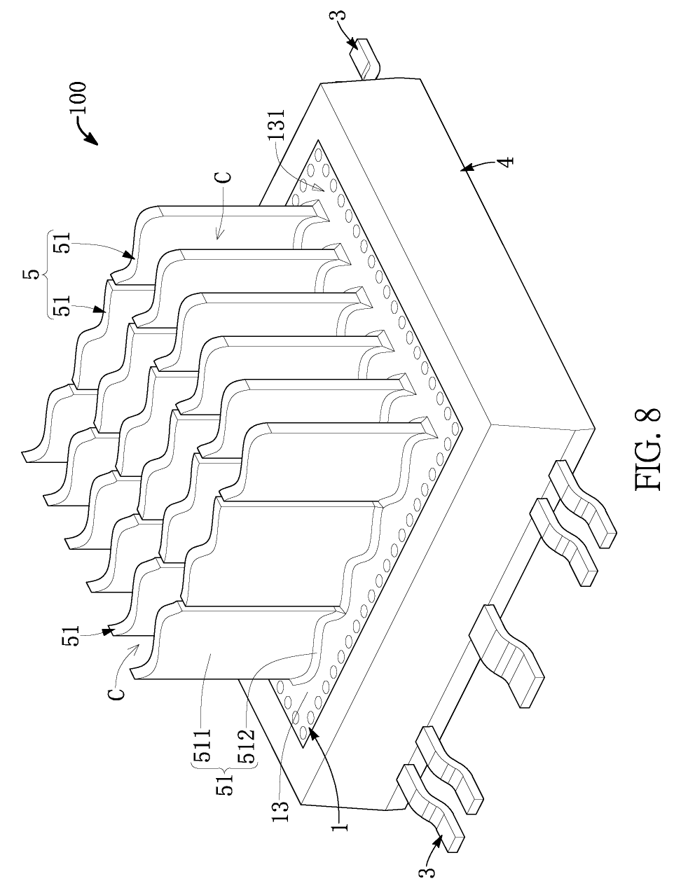

As shown in FIG. 8, each of the thermal conduction members 51 can substantially be an S-shaped column (or a wave-shaped column), and the thermal conduction members 51 are parallel to each other. Any two of the thermal conduction members 51 arranged in each row are arranged adjacent to each other in an end-to-end manner, so that the thermal conduction members 51 in any two rows adjacent to each other can jointly form a wave-shaped space.

Furthermore, in other embodiments of the present disclosure not shown in the drawings, the thermal conduction members 51 shown in FIGS. 5, 7 and 8, and can be in cooperation with each other for forming the predetermined pattern that meets different requirements.

### Second Embodiment

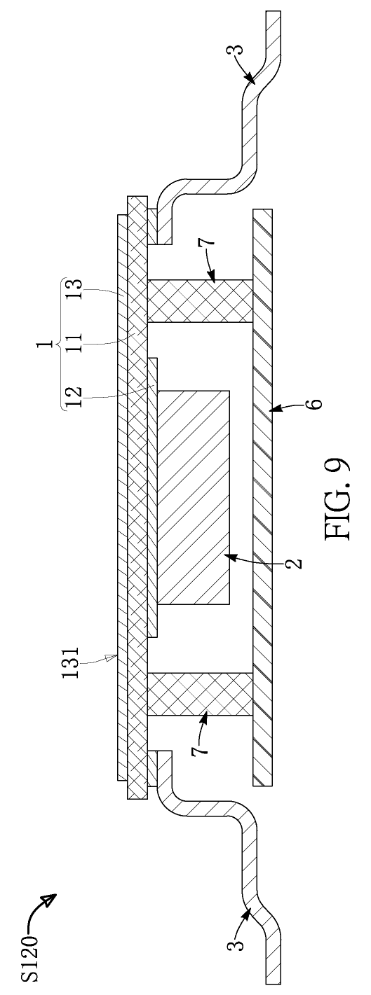

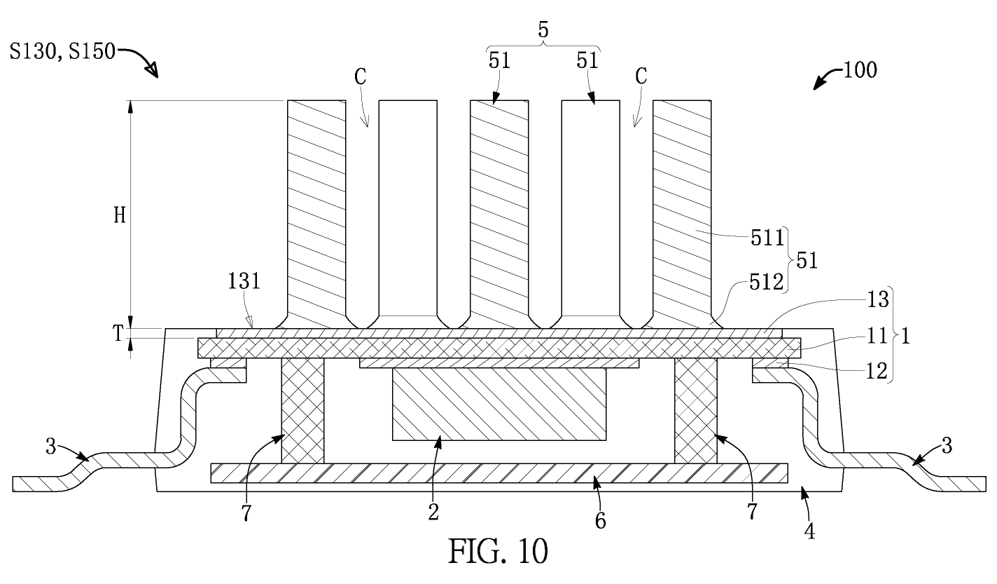

Referring to FIGS. 9 and 10, and a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

In the present embodiment, the manufacturing method further includes a strengthening step S120 that is implemented after the chip-bonding step S110 and before the packaging step S130. The strengthening step S120 is implemented by using one end of a plurality of supporting pillars 7 to connect the substrate 1 and another end of the supporting pillars 7 to connect a carrier 6 being plated, such that the power chip 2 is located between the carrier 6 and the substrate 7.

Specifically, in the packaging step S130, the carrier 6 and the supporting pillars 7 are embedded in the encapsulant 4. Moreover, in the patterning step S150, the carrier 6 absorbs an external force applied to the substrate 1 through the supporting pillars 7 when each of the thermal conduction members 51 is directly fixed onto the flat layout surface 131.

In other words, the power module 100 further includes the carrier 6 and the supporting pillars 7. The carrier 6 is spaced apart from the substrate 1 and is embedded in the encapsulant 4, and the power chip 2 is arranged between the carrier 6 and the substrate 1. Moreover, the supporting pillars 7 are connected in-between the substrate 1 and the carrier 6 and are embedded in the encapsulant 4.

### Third Embodiment

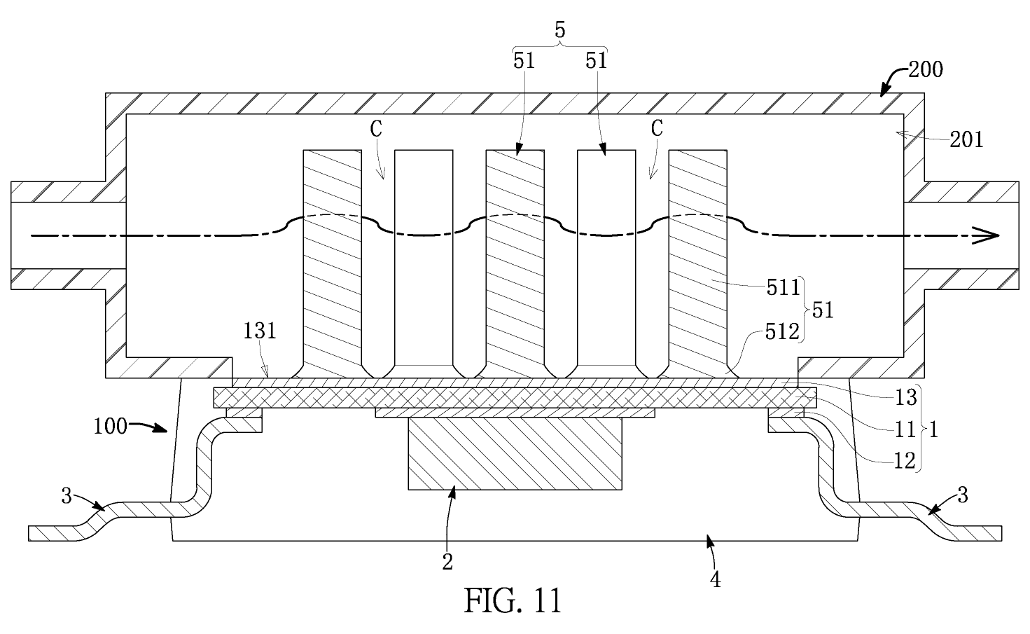

Referring to FIG. 11, a third embodiment of the present disclosure, which is similar to the first and second embodiments of the present disclosure, is provided. For the sake of brevity, descriptions of the same components in the first to third embodiments of the present disclosure (e.g., the power module 100) will be omitted herein, and the following description only discloses different features between the first embodiment and the first and second embodiments.

Specifically, the present embodiment provides an electronic device, which includes a power module 100 and a liquid cooling module 200 that is assembled to the power module 100. It should be noted that the power module 100 of the present embodiment is substantially identical to that of the first embodiment or the second embodiment, and is not described herein for the sake of brevity.

Moreover, the liquid cooling module 200 has a coolant channel 201, and the patterned thermal conduction layer 5 of the power module 100 is arranged in the coolant channel 201. The assembling manner of the power module 100 and the liquid cooling module 200 can be adjusted or changed according to practical requirements, and is not limited by the present embodiment.

### Beneficial Effects of the Embodiments

In conclusion, in any one of the electronic device, the power module, and the manufacturing method provided by the present disclosure, through the structural difference between the patterning portion and the deformed portion of each of the thermal conduction members, when the predetermined pattern is formed by the patterning portions, the connection area of the patterning thermal conduction layer and the flat layout surface can be increased for effectively increasing thermal conduction efficiency from the outer metal layer to each of the thermal conduction members.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A manufacturing method of a power module, comprising:
a chip-bonding step implemented by fixing a power chip onto an inner metal layer of a substrate, wherein the substrate includes an outer metal layer that is opposite to the inner metal layer and that is not electrically coupled to the power chip;
a packaging step implemented by encapsulating the substrate and the power chip in an encapsulant and exposing a flat layout surface of the outer metal layer of the substrate from the encapsulant, wherein the flat layout surface is coplanar with a surface of the encapsulant adjacent thereto; and
a patterning step implemented by directly fixing a plurality of deformed portions of a plurality of thermal conduction members onto the flat layout surface, wherein each of the plurality of thermal conduction members has a patterning portion that is connected to an upper side of the deformed portion thereof, and wherein, in each of the plurality of thermal conduction members, an area of a first cross section of a bottom part of the deformed portion is greater than an area of a second cross section of the patterning portion;
wherein, after the pattering step is implemented, the patterning portions of the plurality of thermal conduction members are spaced apart from each other and are arranged adjacent to each other so as to jointly define a predetermined pattern.

2. The manufacturing method according to claim 1, wherein, in the patterning step, the area of the first cross section of the bottom part of the deformed portion is at least 50% of an area of the flat layout surface.

3. The manufacturing method according to claim 1, further comprising a strengthening step that is implemented after the chip-bonding step and before the packaging step, wherein the strengthening step is implemented by using one end of a plurality of supporting pillars to connect to the substrate and another end of the supporting pillars to connect to a carrier, such that the power chip is located between the carrier and the substrate, wherein, in the packaging step, the carrier and the supporting pillars are embedded in the encapsulant, and wherein, in the patterning step, the carrier absorbs an external force applied to the substrate through the supporting pillars when each of the plurality of thermal conduction members is directly fixed onto the flat layout surface.

4. A power module, comprising:
a substrate including a board, an inner metal layer formed on one side of the board, and an outer metal layer that is formed on another side of the board;
a power chip fixed onto the inner metal layer of the substrate and not electrically coupled to the outer metal layer, wherein the outer metal layer has a flat layout surface arranged away from the power chip;
an encapsulant, wherein the substrate and the power chip are embedded in the encapsulant, and the flat layout surface of the outer metal layer is exposed from the encapsulant and is coplanar with a surface of the encapsulant adjacent thereto; and
a patterned thermal conduction layer including a plurality of thermal conduction members directly fixed onto the flat layout surface, wherein each of the plurality of thermal conduction members has:
a patterning portion, wherein the patterning portions of the plurality of thermal conduction members are spaced apart from each other and are arranged adjacent to each other, and jointly define a predetermined pattern; and
a deformed portion connected to the patterning portion through an upper side of the deformed portion and directly connected to the flat layout surface through a bottom part of the deformed portion, wherein an area of a first cross section of the bottom part of the deformed portion is greater than an area of a second cross section of the patterning portion.

5. The power module according to claim 4, wherein the area of the first cross section of the bottom part of the deformed portion is at least 50% of an area of the flat layout surface.

6. The power module according to claim 4, wherein each of the plurality of thermal conduction members is an elongated column, and the plurality of thermal conduction members are parallel to each other.

7. The power module according to claim 4, wherein the patterning portions of each of the plurality of thermal conduction members has a C-shaped side surface, and wherein, in at least two of the plurality of thermal conduction members adjacent to each other, the C-shaped side surfaces of the patterning portions are staggered with each other, and a part of one of the C-shaped side surfaces is arranged in a space surrounded by another one of the C-shaped side surfaces for jointly defining an S-shaped space.

8. The power module according to claim 4, wherein the plurality of thermal conduction members and the flat layout surface jointly define a thermal conduction channel that is configured to allow a thermal conduction medium to flow therethrough.

9. The power module according to claim 4, wherein the flat layout surface has a plurality of sub-surfaces spaced apart from each other, and the plurality of thermal conduction members are directly fixed onto the plurality of sub-surfaces of the flat layout surface, respectively.

10. The power module according to claim 4, further comprising:
a carrier embedded in the encapsulant, wherein the power chip is arranged between the carrier and the substrate; and
a plurality of supporting pillars that are connected in-between the substrate and the carrier and that are embedded in the encapsulant.

11. The power module according to claim 4, further comprising a plurality of pins that are fixed to the inner metal layer and that are electrically coupled to the power chip, wherein a part of each of the plurality of pins protrudes from the encapsulant.

12. An electronic device, comprising:
a power module including:
a substrate including a board, an inner metal layer formed on one side of the board, and an outer metal layer that is formed on another side of the board;
a power chip fixed onto the inner metal layer of the substrate and not electrically coupled to the outer metal layer, wherein the outer metal layer has a flat layout surface arranged away from the power chip;
an encapsulant, wherein the substrate and the power chip are embedded in the encapsulant, and the flat layout surface of the outer metal layer is exposed from the encapsulant and is coplanar with a surface of the encapsulant adjacent thereto; and
a patterned thermal conduction layer including a plurality of thermal conduction members directly fixed onto the flat layout surface, wherein each of the plurality of thermal conduction members has:
a patterning portion, wherein the patterning portions of the plurality of thermal conduction members are spaced apart from each other and are arranged adjacent to each other, and jointly define a predetermined pattern; and
a deformed portion connected to the patterning portion through an upper side of the deformed portion and directly connected to the flat layout surface through a bottom part of the deformed portion, wherein an area of a first cross section of the bottom part of the deformed portion is greater than an area of a second cross section of the patterning portion; and
a liquid cooling module assembled to the power module, wherein the liquid cooling module has a coolant channel, and the patterned thermal conduction layer of the power module is arranged in the coolant channel.
